(19) United States
(12) Patent Application Publication
(10) Pub. No.: US 2009/0108278 A1
(43) Pub. Date: Apr. 30, 2009

(54) Manufacturing Method of an Antistatic Flip Chip Substrate Connected to Several Chips

(76) Inventors: Liann-Be Chang, Dasi Township (TW); Hsin-Yi Chang, Kaohsiung City (TW); Kuo-Ling Chiang, Taoyuan City (TW)

Correspondence Address: Alan D. Kamrath;Kamrath & Associates, Suite 245, P.A. 4825 Olson Memorial Highway, Golden Valley, MN, 55422, US

(21) Appl. No.: 11/930,404

(22) Filed: Oct. 31, 2007

(51) Int. Cl. H01L 33/00

(52) U.S. Cl. 257/98; 438/27; 257/E33.056; 257/E33.067

(57) ABSTRACT

The present invention provides the manufacturing method and device of an antistatic flip chip substrate that can be connected to several chips; this device could protect LED semiconductors against electrostatic discharge damage, and also save cost and space for the assembly of LED semiconductors.

### BACKGROUND OF INVENTION

1. Field of the Invention

The present invention relates generally to the manufacturing method and device of an antistatic flip chip substrate that can be connected to several chips, and more particularly to those which allow several conductors of lighting panel to be connected to the flip chip substrate.

2. Description of Related Art

The capacitor structure of typical CIC flip chip semiconductor can be only linked to a LED semiconductor, so a single LED semiconductor will require for a CIC flip chip substrate, and so on, thus resulting in higher cost and bigger space.

### SUMMARY OF THE INVENTION

The present invention provides the manufacturing method and device of an antistatic flip chip substrate that can be connected to several chips. As some steps are taken to provide graphic representation of semiconductor of CIC flip chip substrate, a CIC flip chip substrate can be linked to several LED semiconductor structures, thus leading to cost-effective and space-saving advantages.

### DETAILED DESCRIPTION OF THE INVENTION

The features and the advantages of the present invention will be more readily understood upon a thoughtful deliberation of the following detailed description of a preferred embodiment of the present invention with reference to the accompanying drawings.

The present invention provides the manufacturing method and device of an antistatic flip chip substrate that can be connected to several chips.

Referring to FIGS. 1□4, the manufacturing steps are as follows:

Step 1 (S1): this step is to manufacture several LED semiconductors, each of which permits a substrate 10 to be assembled with a nucleation layer 11, a conductive buffer layer 12, a positive layer 13, an upper confinement layer 131, a lower confinement layer 132, a contact layer 14, a first electrode 15 and a second electrode 16.

Of which, the first electrode 15 can be silver-coated as a reflective layer, so that LED semiconductor has better luminescence effect.

Step 2 (S2): this step is to manufacturer a CIC flip chip substrate 20, which comprises a semiconductor layer, an insulating layer and a semiconductor substrate.

The semiconductor substrate is made of highly heat-dissipating materials (incl. aluminum nitride), which feature high heat-dissipation and cost-effectiveness.

The insulating layer is made of dielectric material, superdielectric material and over-voltage breakdown material, which contain silicon dioxide, silicon nitride, hafnium dioxide, zirconium dioxide and rare-earth oxide.

Step 3 (S3): the semiconductor layer of CIC flip chip substrate 20 is formed a graphic representation 24 (shown in FIG. 4) and a plurality of first electrodes 21 and second electrodes 22.

Step 4 (S4): the first electrode 15 and second electrode 16 of every LED semiconductor are electrically linked to the first electrode 21 and second electrode 22 of CIC flip chip substrate 20 through solder beads 23.

The light emitted from LED is not uniform, e.g. LED street lamp doesn't irradiate laterally. So, when the semiconductor layer of CIC flip chip substrate 20 is formed the graphic representation 24, the graphic representation 24 is configured in such a manner that several LEDs are linked to CIC flip chip substrate 20 to form a desirable optical field, which can also be achieved through different patterns of embedded flip chips on the substrate.

Some reflective cavities are formed on the CIC flip chip substrate 20, each of which could accommodate at least a LED; when LED is highlighted, light-gathering effect could be achieved through this cavity, along with longer emitting distance and brighter effect.

When a forward bias is applied between V+ and V− under normal operation, a current flows through the semiconductor from the first electrode 15, and the generated light 30 is discharged from the substrate 10; in the event of occurrence of abnormal voltage or electrostatic charge, the discharge path is turned to CIC flip chip substrate 20, without passing through the semiconductor. In such case, the protective system will be activated at 200V to guarantee that the human body can withstand voltage up to 8 KV.

The present invention could protect LED semiconductor against static discharge damage. Moreover, some steps are taken to represent graphically the semiconductor layer of CIC flip chip substrate 20, so a single CIC flip chip substrate 20 could be connected to several LED semiconductors.

Owing to high degree of heat generated from several LED semiconductors of the present invention, the CIC flip chip substrate 20 must have a strong heat-dissipating capacity, so that several LED semiconductors can be linked to a single CIC flip chip substrate 20; thus, the semiconductor substrate of CIC flip chip substrate 20 may be made of silicon or aluminum nitride, so that LED semiconductors could provide desirable heat-dissipating effect at an attractive price.

The present invention could provide another antistatic flip chip substrate that can be connected to several chips. Referring to FIGS. 2-4, it comprising:

at least a LED semiconductor, each of which permits a substrate 10 to be assembled with a nucleation layer 11, a conductive buffer layer 12, a positive layer 13, an upper confinement layer 131, a lower confinement layer 132, a contact layer 14, a first electrode 15 and a second electrode 16;

of which, the first electrode 15 can be silver-coated as a reflective layer.

a CIC flip chip substrate 20, which comprises a semiconductor layer, an insulating layer and a semiconductor substrate; the semiconductor layer of CIC flip chip substrate 20 is formed a graphic representation 24 (shown in FIG. 4) and a plurality of first electrodes 21 and second electrodes 22; the first electrode 15 and second electrode 16 of every LED semiconductor are electrically linked to the first electrode 21 and second electrode 22 of CIC flip chip substrate 20 through solder beads 23.

The semiconductor substrate on CIC flip chip substrate 20 is made of highly heat-dissipating materials (incl. aluminum nitride).

The insulating layer CIC flip chip substrate 20 is made of dielectric material, superdielectric material and over-voltage breakdown material, which contain silicon dioxide, silicon nitride, hafnium dioxide, zirconium dioxide and rare-earth oxide.

Some reflective cavities are formed on the CIC flip chip substrate 20, each of which could accommodate at least a LED; when LED is highlighted, light-gathering effect could be achieved through this cavity, along with longer emitting distance and brighter effect.

### BRIEF DESCRIPTION OF THE DRAWINGS

FIG. 1 shows a flow process chart of the present invention.

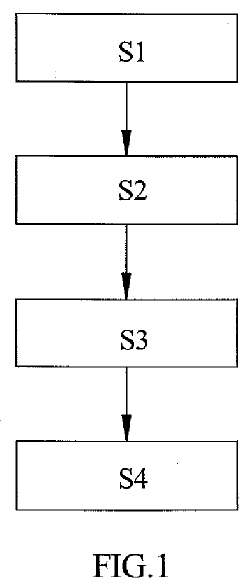

FIG. 2 shows a general view of LED semiconductor of the present invention.

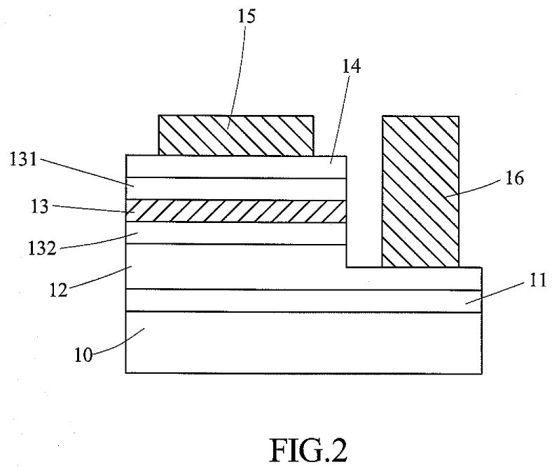

FIG. 3 shows a constitutional view of LED semiconductor and CIC flip chip substrate of the present invention.

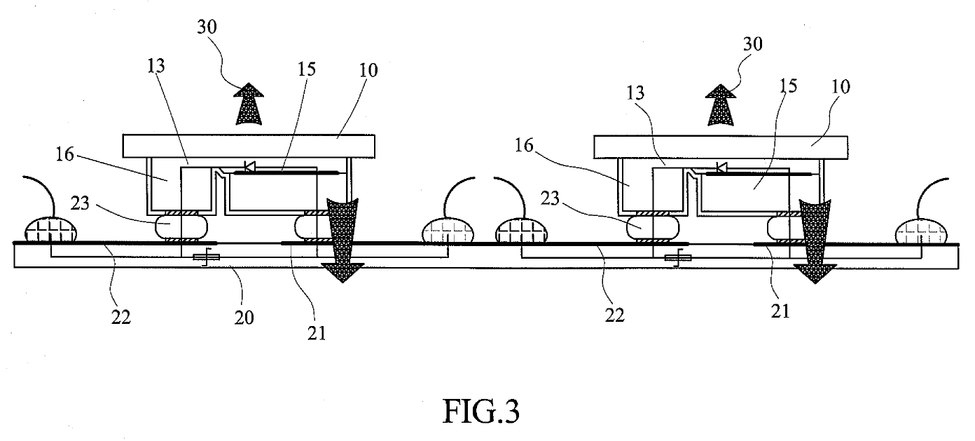

FIG. 4 shows a layout of graphic representation of semiconductor layer of the present invention.

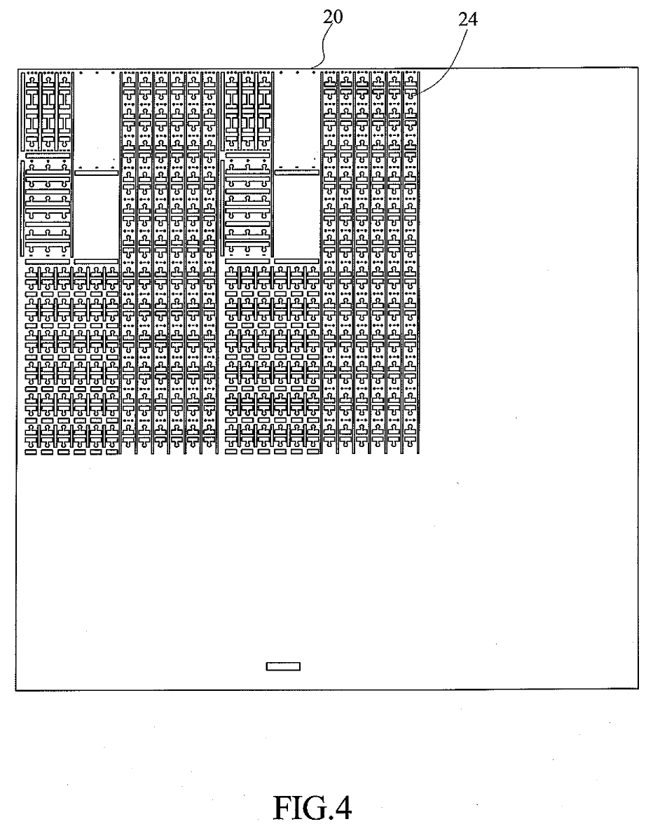

1. A manufacturing method of antistatic flip chip substrate that can be linked to several chips, which comprises the following steps:
Step 1: to manufacture several LED semiconductors, each of which has a first electrode and a second electrode;
Step 2: to manufacturer a CIC flip chip substrate, which comprises a semiconductor layer, an insulating layer and a semiconductor substrate; the semiconductor substrate is made of highly heat-dissipating materials;
Step 3: the semiconductor layer of CIC flip chip substrate is formed a graphic representation and a plurality of first electrodes and second electrodes;
Step 4: the first electrode and second electrode of every LED semiconductor are electrically linked to the first electrode and second electrode of CIC flip chip substrate.

2. The method defined in claim 1, wherein every LED semiconductor permits the substrate to be assembled a nucleation layer, a conductive buffer layer, a positive layer, an upper confinement layer, a lower confinement layer, a contact layer, a first electrode and second electrode.

3. The method defined in claim 1, wherein the first electrode of said LED semiconductor can be silver-coated as a reflective layer.

4. The method defined in claim 1, wherein said semiconductor substrate is made of aluminum nitride.

5. The method defined in claim 1, wherein said insulating layer is made of dielectric material.

6. The method defined in claim 1, wherein said insulating layer is made of superdielectric material.

7. The method defined in claim 1, wherein said insulating layer is made of over-voltage breakdown material.

8. The method defined in claim 1, wherein said insulating layer is made of hafnium dioxide.

9. The method defined in claim 1, wherein said insulating layer is made of zirconium oxide.

10. The method defined in claim 1, wherein said insulating layer is made of silicon dioxide.

11. The method defined in claim 1, wherein said insulating layer is made of silicon nitride.

12. The method defined in claim 1, wherein said insulating layer is made of rare-earth oxide.

13. The method defined in claim 1, wherein said CIC flip chip substrate is formed the graphic representation, and the graphic representation is configured in such a manner that several LEDs are linked to CIC flip chip substrate to improve the non-uniform optical field through the graphic representation.

14. The method defined in claim 1, wherein some reflective cavities are formed on said CIC flip chip substrate, and each cavity could accommodate at least a LED to achieve light-gathering effect.

15. An antistatic flip chip substrate that can be linked to several chips, which comprising:
at least a LED semiconductor, each of which includes a first electrode and a second electrode;
a CIC flip chip substrate, which comprises a semiconductor layer, an insulating layer and a semiconductor substrate; the semiconductor layer on CIC flip chip substrate forms a graphic representation and a plurality of first electrodes and second electrodes; the first electrode and second electrode of every LED semiconductor are electrically linked to the first electrode and second electrode of CIC flip chip substrate.

16. The device defined in claim 15, wherein the first electrode of said LED semiconductor can be silver-coated as a reflective layer.

17. The device defined in claim 15, wherein some reflective cavities are formed on said CIC flip chip substrate, and each cavity could accommodate at least a LED.
